(19) United States
(12) Patent Application Publication
(10) Pub. No.: US 2009/0133838 A1
(43) Pub. Date: May 28, 2009

(54) Plasma Processor Apparatus

(75) Inventor: Kazuhisa MIYAGAWA, Kanagawa (JP)

Correspondence Address: CROWELL & MORING LLP;INTELLECTUAL PROPERTY GROUP, P.O. BOX 14300, WASHINGTON, DC, 20044-4300, US

(73) Assignee: TOKYO ELECTRON LIMITED, Tokyo (JP)

(21) Appl. No.: 12/349,551

(22) Filed: Jan. 7, 2009

Related U.S. Application Data
(62) Division of application No. 10/507,524, filed on Sep. 14, 2004.

(30) Foreign Application Priority Data
Mar. 14, 2002 (JP) 2002-070504

(51) Int. Cl. H01L 21/3065; C23C 16/54

(52) U.S. Cl. 156/345.35; 118/723 ER

(57) ABSTRACT

An electromagnetic field generating coil included in plasma processing apparatus is realized with a balanced transmission line. Conductors constituting the balanced transmission line are disposed vertically above a wafer. A uniform electromagnetic field is generated in parallel with the wafer using the balanced transmission line. A gas inlet is formed above the balanced transmission line so that a gas will flow into the wafer after passing through the electromagnetic field generated around the balanced transmission line. The balanced transmission line may be formed spirally.

### CROSS REFERENCE TO RELATED APPLICATION

This application is a divisional application of U.S. application Ser. No. 10/507,524, filed Sep. 14, 2004, which is a National Phase application of PCT/JP2003/003116, filed Mar. 14, 2003, which claims priority under 35 U.S.C. §119 to Japanese Patent Application No. 2003-070504, filed Mar. 14, 2002, the entire disclosure of which are herein expressly incorporated by reference.

### BACKGROUND OF THE INVENTION

1. Field of the Invention

The present invention relates to plasma processing apparatus, or more particularly, to plasma processing apparatus for performing, for example, plasma chemical vapor deposition (CVD) or plasma etching in the course of manufacturing a semiconductor.

2. Description of the Related Art

In the past, plasma has been utilized in a process of performing coating or layering, surface refining, etching, or the like, and has contributed to great successes. The plasma may be referred to as a state attained when an inert gas or a reactive gas introduced into an electromagnetic field, which is generated by a direct current, a high-frequency wave, or a microwave, while being depressurized is ionized through the collision of accelerated electrons and gaseous molecules. Thus, the plasma is composed of particles such as chemically active ions and free radicals (excitation atoms or molecules).

For example, a plasma CVD technology is a technology for forming a thin film by facilitating chemical reaction of active particles, which are generated during ionization of a reactive gas resulting in plasma, on the surface of a substrate.

Moreover, dry etching is etching to be performed using free radicals and ions produced by decomposing an etching gas through discharge. The direction and energy of ionic movement are controlled with an electric field, whereby anisotropic etching is performed on a sample placed on a high-frequency electrode.

Plasma processing apparatus uses plasma in a vacuum chamber to perform coating or layering, surface refining, and etching. Herein, homogeneous plasma must be produced in order to provide a substrate or the like with a uniform property. In particular, for plasma CVD apparatus or etching apparatus employed in manufacturing a semiconductor, homogeneous plasma must be produced in order to uniformly coat or layer the surface of a wafer or uniformly machine it. Nowadays, the diameter of wafers has come to be as large as 12 inches and processes have come to be performed at lower temperatures. The necessity of producing homogeneous plasma over the surface of a wafer has increased. For production of the homogeneous plasma, an electromagnetic field must be generated uniformly. The generation of a uniform electromagnetic field is a critical problem that must be overcome.

In inductively coupled plasma etching apparatus that is an example of conventional plasma processing apparatus, a high-frequency coil is wound around the side of a cylindrical process chamber in order to generate a high-frequency electromagnetic field within the chamber. However, the density of a generated electromagnetic field is lower in the center of the coil than in the periphery thereof. It is hard to generate a uniform electromagnetic field.

The density of an electric field or magnetic field is inversely proportional to the distance from a conductor of a coil. Namely, a magnetic field strength H at a point separated from the conductor, through which a current I flows, by a distance R is expressed as H=I/2πR (A/m). Moreover, an electric field strength at a point separated from the conductor, of which charge per unit length is Q, by the distance R is expressed as E=Q/2πεR (v/m).

Consequently, the electric or magnetic field density is the highest in the vicinity of the coiled conductor, and is the lowest in the center of the coil. Eventually, a generated electromagnetic field strength is the highest near the coil and the lowest in the center of the coil.

Moreover, when a coil is spirally disposed in the upper part of a process chamber, the impedance of the spiral coil varies depending on a type of process chamber. This poses a problem in that it is hard to attain an impedance match relative to the spiral coil through which a high-frequency wave is propagated.

Furthermore, in plasma processing apparatus having a multi-spiral structure realized with a plurality of spiral coils, an electromagnetic field density is different between a point near the coils and a point away from them. It is hard to generate a uniform electromagnetic field.

According to a method of producing plasma by utilizing a radiation field emitted from an antenna, a slot antenna or a spoke antenna may be adopted as a means for generating a uniform electromagnetic field. However, the antennas are characterized by a concentric directional pattern whose center corresponds to a feeding point, and the electric fields from the antennas are, as expressed as E=60πIL/λR (v/m) (where I denotes a current, L denotes the electrical length of an antenna, and λ denotes a wavelength), inversely proportional to the distance R from the feeding point. Consequently, it is hard to generate a uniform electromagnetic field in a planar direction.

The dimension of the antenna is restricted to a value equivalent to a quarter wavelength attained at a certain frequency. For example, if a frequency employed is 80 MHz, the quarter wavelength attained at the frequency is approximately 90 cm. It is difficult to adapt such antenna to a process chamber. Moreover, a radiated electromagnetic wave reflects from or interferes with the wall surface of the process chamber. It is difficult to control for generating a desired electromagnetic field.

### SUMMARY OF THE INVENTION

Accordingly, an object of the present invention is to provide plasma processing apparatus capable of efficiently introducing a high-frequency power so as to generate a uniform electromagnetic field.

In order to efficiently introduce a high-frequency power for generation of a uniform electromagnetic field, the present invention has a coil, which generates an electromagnetic field, formed with a balanced transmission line. Herein, two conductors constituting the balanced transmission line are disposed vertically.

In the balanced transmission line, if a load impedance at a terminal is equal to the characteristic impedance of the balanced transmission line, an impedance match is attained, and an electromagnetic wave is entirely formed with a traveling wave alone. Consequently, a high-frequency power is efficiently transmitted, and a generated electromagnetic field advances in the direction of the transmission and is therefore uniform in the direction thereof.

Moreover, since the two conductors constituting the balanced transmission line are disposed vertically, a uniform electromagnetic field parallel to the surface of a wafer can be generated.

Furthermore, as long as a loss caused by the balanced transmission line can be ignored, the characteristic impedance of the balanced transmission line is expressed as Z=\sqrt{L/C} and does not depend on the high frequency. An impedance match can be attained without changing the characteristic impedance relative to a different frequency.

The balanced transmission line may be curved and disposed above a wafer. In particular, when the balanced transmission line is shaped spirally or tortuously, an electromagnetic field can be generated more uniformly.

An area on a plane occupied by the balanced transmission line employed in the present invention is so small that a gas passageway can be widely preserved. A gas can be readily introduced from above.

When high-frequency power is attenuated in an advancing direction in which an electromagnetic field advances, the attenuation of power can be compensated by gradually narrowing the spacing between of the balanced transmission line, for example, the spacing between adjoining portions of a spiral or tortuous shape.

Even when an electromagnetic field loses uniformity due to any external factor, the electromagnetic field can be corrected to be uniform by adjusting the spacing between adjoining portions of the balanced transmission line.

The balanced transmission line may be disposed outside a vacuum chamber. Moreover, one of the two conductors constituting the balanced transmission line may be disposed in the vacuum chamber, and the other. conductor may be disposed on an atmospheric pressure side outside the vacuum chamber. In this case, a gas passageway is formed in a dielectric supporting the balanced transmission line. Thus, the efficiency in ionization resulting in plasma can be improved.

Moreover, the balanced transmission line may have two dielectric plates, each of which has one conductor, disposed with a space between them. Herein, the space may be used as a gas introduction path.

When the balanced transmission line is disposed within the vacuum chamber, the balanced transmission line may also be used as a heater. This leads to a simplified configuration.

If a conducting strip included in a microstrip is disposed in the vacuum chamber, the microstrip may be substituted for the balanced transmission line. In this case, a gas passageway is formed in a dielectric plate. A structure having a wire disposed in a space above a grounded conducting plane may be adopted as the microstrip. In this case, the space on the grounded conducting plane and the wire are disposed in a vacuum chamber, and a gas is introduced into the space between the grounded conducting plane and wire. This results in a simplified configuration.

### BRIEF DESCRIPTION OF THE DRAWINGS

The present invention will be described below with reference to appended drawings:

FIG. 1 schematically shows plasma processing apparatus in which the present invention is implemented;

FIG. 2 shows a spiral balanced transmission line employed in the present invention;

FIG. 3 shows part of the spiral balanced transmission line employed in the present invention;

FIG. 4A shows a tortuous balanced transmission line employed in the present invention;

FIG. 4B shows a flow of a current through the tortuous balanced transmission line employed in the present invention;

FIG. 5 shows an embodiment of the present invention having a balanced transmission line disposed on an atmospheric pressure side;

FIG. 6 shows an embodiment of the present invention having a gas introduction path formed in a dielectric included in a balanced transmission line;

FIG. 7 shows another embodiment of the present invention having a gas introduction path formed in a dielectric included in a balanced transmission line;

FIG. 8 shows an embodiment of the present invention having a balanced transmission line used as a heater; and

FIG. 9 shows another embodiment of the present invention having a balanced transmission line used as a heater.

### DESCRIPTION OF THE PREFERRED EMBODIMENTS

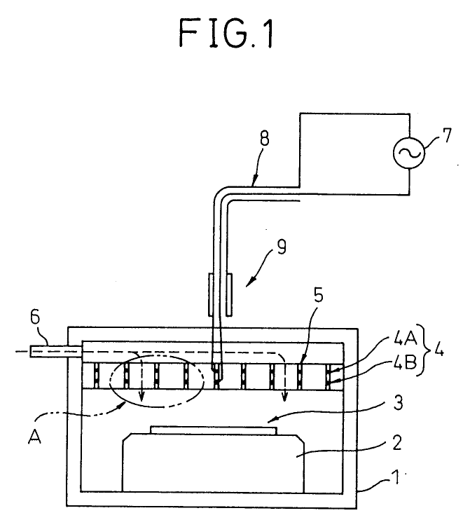

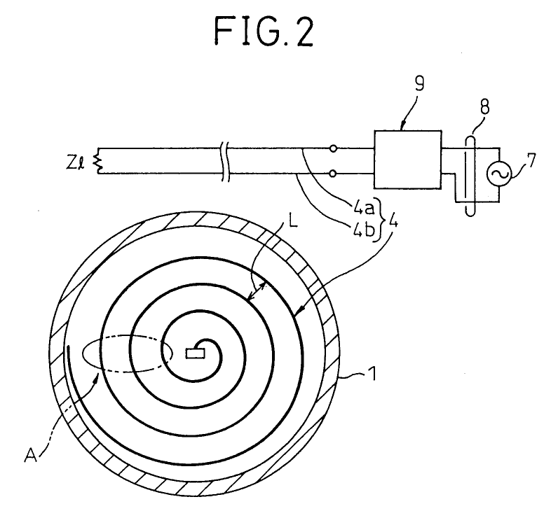

FIG. 1 schematically shows an embodiment of plasma processing apparatus in which the present invention is implemented. FIG. 2 schematically shows a spiral balanced transmission line employed in the present invention.

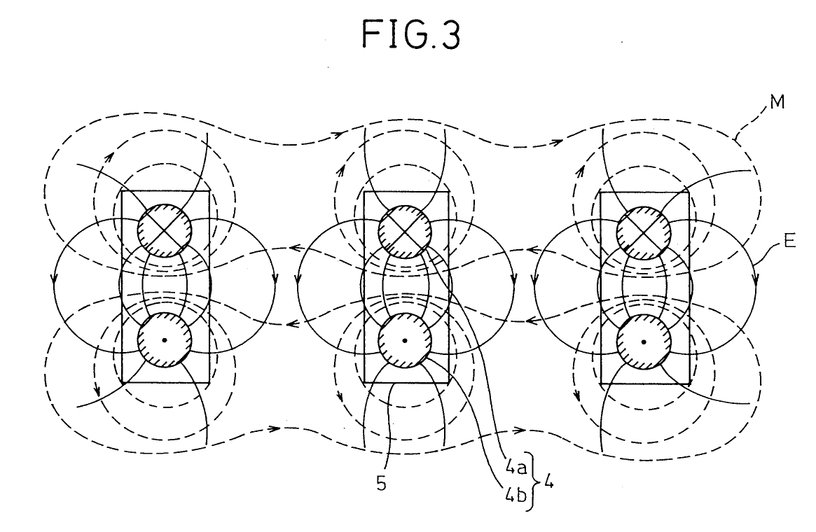

According to an embodiment of the present invention, a plasma process chamber 1 is formed as a cylindrical vacuum chamber made of A1 or the like. A susceptor 2 on which a wafer 3 is placed is put in the process chamber 1. A balanced transmission line 4 connected to a high-frequency power supply 7 over a coaxial cable 8 via a balun 9. The balanced transmission line 4 is sheathed with a dielectric 5 that supports, insulates, and protects the balanced transmission line (see FIG. 3). Two conductors 4a and 4b constituting the balanced transmission line are disposed vertically above the wafer 3, and spirally extended from the center of the wafer or chamber to the periphery thereof.

The cross-sectional shape of the conductors 4a and 4b of the balanced transmission line may be a round, a square, or the like. Assuming that the cross-sectional shape is a round, a conductor whose diameter ranges from 5 mm to 10 mm is adopted as the conductors 4a and 4b. Even if a conductor having any other cross-sectional shape is adopted, the conductor should have a similar size. The spacing between the two conductors 4a and 4b constituting the balanced transmission line is not very small but ranges from about 40 mm to about 60 mm. The spacing L between adjoining portions of the spiral may be one time or 1.5 times larger than the spacing between the two conductors 4a and 4b constituting the balanced transmission line. The distance of the balanced transmission line from the wafer 3 ranges about 5 cm to about 10 cm.

Since the balanced transmission line 4 is stored in the vacuum chamber, it should be fully sheathed with the dielectric 5 made of a ceramic or the like. The conductors 4a and 4b may be made of any material. If the conductors must withstand high temperature, a tungsten wire or a molybdenum wire may be adopted. However, since the conductors 4a and 4b must withstand plasma or be prevented from metal pollution, the conductors should be coated with a ceramic such as a nitride, carbide, or an oxide according to such a method as thermal spraying, or should be enclosed with a ceramic according to such a fabrication method as hot-pressing. Moreover, both the two conductors may not be sheathed together with a dielectric but two transmission lines each sheathed with a dielectric may be disposed vertically and adopted as a balanced transmission line.

A high-frequency power is introduced into the balanced transmission line 4 from the high-frequency power supply 7 over the coaxial cable 8 via the balun 9 through the center of the top of the process chamber. A current to be fed from the coaxial cable 8 that is an unbalanced line to the balanced transmission line 4 is converted by the balun 9. The balun 9 is realized with a Sperrtopf balun having a coaxial cable sheathed with a cylindrical tube whose electrical length is a quarter wavelength. A load that presents a load impedance Z1 is coupled to a terminal of the balanced transmission line, whereby an impedance match is attained.

A high-frequency power may not be introduced through the center of the balanced transmission line but may be introduced through the periphery thereof and connected to a load in the center thereof. If the high-frequency power is introduced through the periphery of the balanced transmission line, the high-frequency power may not be introduced through the top of the chamber but may be introduced through the side of the chamber.

Moreover, if the process chamber 1 is rectangular, the balanced transmission line may have a rectangular spiral shape accordingly.

An electromagnetic field power around the balanced transmission line 4 is consumed during ionization and therefore the electromagnetic field is attenuated. If the spacing L between adjoining portions of the spiral is adjusted to get gradually narrowed in consideration of an attenuation ratio, uniformity can be attained.

Moreover, if an electromagnetic field loses uniformity due to an external factor, the spacing L between adjoining portions of the spiral is adjusted in order to correct the electromagnetic field. Thus, a uniform electromagnetic field can be generated.

A gas inlet 6 to introduce a gas is formed above the balanced transmission line 4. According to the present invention, an area on a plane occupied by the balanced transmission line 4 is so small that even when a gas is introduced above the balanced transmission line 4, the gas substantially flows into the surface of a wafer. Moreover, since the gas passes through the balanced transmission line 4, plasma is efficiently produced owing to a uniform electromagnetic field.

The manner in which the balanced transmission line 4 is arranged depends on a design. The top or bottom of the balanced transmission line 4 may be supported using a dielectric plate. In this case, through-holes are formed as a gas path in the supporting dielectric plate.

In FIG. 1, the gas inlet 6 is formed at one position. Alternatively, the gas inlet may be formed at a plurality of positions, or different gas inlets may be formed in order to introduce different gases. If a plurality of gas inlets is symmetrically formed with respect to the center of the chamber, the flow of a gas will become more uniform. The gas inlet may be formed not only in the side of the process chamber but also in the top thereof.

Moreover, when each of the conductors of the balanced transmission line are disposed vertically, a gas inlet may be interposed between the conductors so that a gas will be directly introduced into the space between the conductors. In some cases, a gas inlet may be formed below the balanced transmission line.

The structure of the susceptor 2 to lay the wafer 3 is identical to the conventional one, and the description of the structure will therefore be omitted. If necessary, a lower electrode may be formed in the susceptor in order to apply a high-frequency bias to the wafer. Moreover, a gate valve through which a wafer is carried in or out, a pipe for a vacuum pump, and other components necessary for plasma processing apparatus, which are not shown, are included in the same manner as the conventional apparatus.

FIG. 3 shows an electromagnetic field in a portion A shown in FIG. 1 and FIG. 2.

A x mark drawn in the conductor 4a of the balanced transmission line 4 as shown in FIG. 3 signifies that a current flows from the front side of the sheet of paper of the drawing to the rear side thereof. A dot mark drawn in the conductor 4b thereof signifies that the current flows from the rear side of the sheet of paper of the drawing to the front side thereof. Namely, the current in the upper conductor 4a flows from the front side of the sheet of paper of the drawing to the rear side thereof, while the current in the lower conductor 4b flows from the rear side thereof to the front side thereof. An electric field E is indicated with a solid line, and a magnetic field M is indicated with a dashed line. The magnetic field is generated as indicated with the dashed line between the conductors 4a and 4b and near the conductors. The magnetic field M is generated uniformly nearly parallel to the surface of a wafer.

FIG. 3 shows part of a cross section of a spiral along a radius thereof. In the cross section thereof along an opposite radius that is symmetrical to the radius with respect to the center of the chamber, currents flow in opposite directions. Namely, the current in the upper conductor 4a flows from the rear side of the sheet of paper of the drawing to the front side thereof, and the current in the lower conductor 4b flows from the front side thereof to the rear side thereof. However, the magnetic field is, as mentioned above, generated uniformly parallel to the surface of a wafer. Moreover, when the half wavelength of the current is shorter than a coil length to a terminal resistor, the electric field and magnetic field are inverted depending on a position in the radial direction. However, since the magnetic field and electric field instantaneously move in the direction of propagation, they are uniform in the direction of propagation.

As mentioned above, an electromagnetic field generated around a coil that is formed spirally using the balanced transmission line 4 is parallel to a wafer and nearly uniform in a circumferential direction and a radial direction. The generated plasma is therefore nearly homogeneous.

Moreover, since the characteristic impedance of the balanced transmission line 4 is not frequency-dependent, a wide band of frequencies can be utilized. This leads to a wide range of applications of the apparatus.

An electromagnetic field generated around the balanced transmission line 4 is a combination of electromagnetic fields generated by every portions of the conductors 4a and 4b constituting the balanced transmission line 4. Namely, since the electromagnetic field is a combination of electromagnetic fields generated by positive and negative conductors disposed with a certain distance between them. The electromagnetic fields generated by the conductors 4a and 4b are canceled out at a distant position in which the distance between the conductors 4a and 4b can be ignored.

Consequently, when the spacing between the conductors 4a and 4b constituting the balanced transmission line is smaller, the electromagnetic fields are canceled out to a greater extent. The electromagnetic fields detected near the conductors tend to diminish. If there is a large spacing between the conductors 4a and 4b, the extent to which the electromagnetic fields are canceled out decreases. The electromagnetic fields get stronger but cannot be confined to the space in the chamber. Moreover, the characteristic impedance of the transmission line changes. Consequently, when these conditions are taken into consideration, if a round conductor is adopted as the conductors 4a and 4b, the diameter of the round conductor should, as mentioned above, range from about 5 mm to about 10 mm. The spacing between the conductors 4a and 4b constituting the balanced transmission line should range from about 40 mm to about 60 mm.

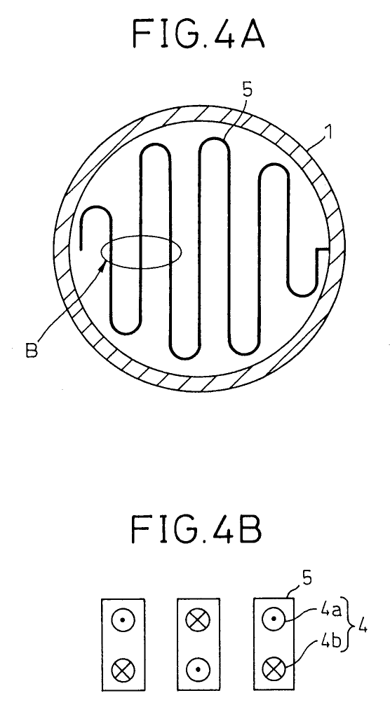

As shown in FIG. 4A, the balanced transmission line 4 may not be shaped spirally but may be shaped tortuously in line with the shape of the process chamber. Thus, a tortuous coil 5 may be formed. In this case, a high-frequency wave is introduced through the side of the process chamber.

FIG. 4B shows the flow of a current in a portion B shown in FIG. 4A. Marks drawn in the conductors 4a and 4b constituting the balanced transmission line 4 have the same meanings as those shown in FIG. 3 and indicate the directions of currents. When the balanced transmission line 4 is shaped tortuously, unlike when it is shaped spirally, the directions of the currents flowing through the respective conductors are different between adjoining portions of the transmission line. This is disadvantageous to induction of an electromagnetic field. However, a uniform electromagnetic field can be generated in the same manner as it is when the balanced transmission line is shaped spirally. Moreover, when the corner portions of the tortuous transmission line are twisted in order to invert the transmission line, the directions of the flowing currents become unchanged between the adjoining portions of the transmission line in the same manner as they are when the balanced transmission line is shaped spirally.

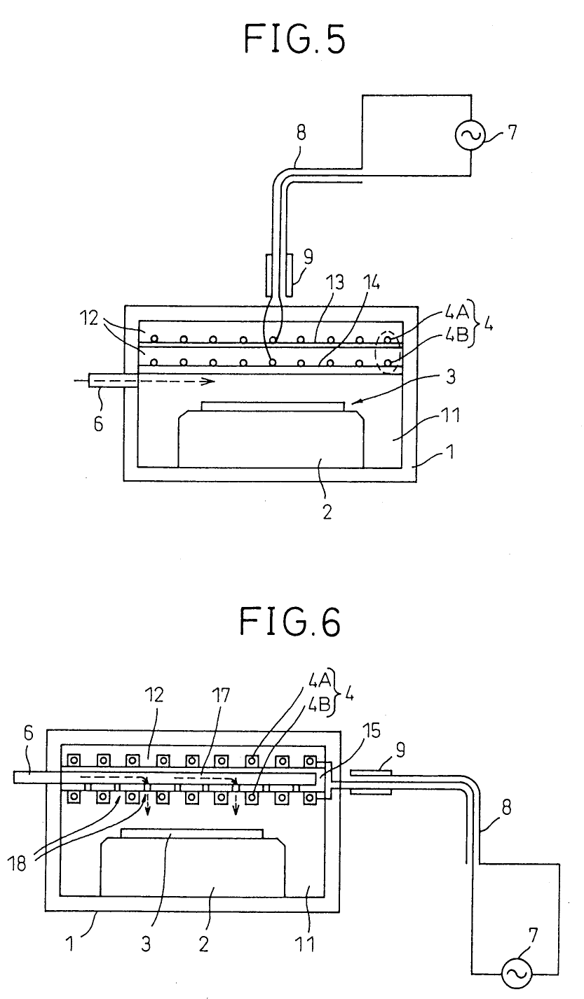

In an embodiment shown in FIG. 5, a spiral balanced transmission line 4 is not disposed on a vacuum side 11 on which plasma is generated but is disposed on an atmospheric pressure side 12 when the coil is disposed on the atmospheric pressure side 12, the conductors of the coil are left unaffected by the plasma. This expands the freedom in selecting a coil. Referring to FIG. 5, conductors 4a and 4b are formed spirally on two dielectric plates 13 and 14 respectively, and the terminals of the conductors are connected to a load that presents a load impedance. The conductors 4a and 4b constitute a balanced transmission line 4. Herein, the dielectric plate 14 is made of, for example, quartz and serves as a top plate partitioning the vacuum chamber from the atmospheric pressure chamber.

In this case, a gas inlet 6 is formed below the balanced transmission line 4. Compared with the case shown in FIG. 1 where the balanced transmission line 4 is disposed within the vacuum chamber, an electromagnetic field utilized for generation of plasma is limited. However, a uniform electromagnetic field can be generated in the same way.

In an embodiment shown in FIG. 6, one of two conductors 4a and 4b constituting a balanced transmission line 4 and sandwiching a dielectric plate, that is, the conductor 4a is disposed on an atmospheric pressure side 12, and the other conductor 4b is disposed on a vacuum side 11. In this case, the conductors 4a and 4b constituting the balanced transmission line are disposed on the front and back sides of a dielectric plate 15. The dielectric plate 15 has a gas passageway 17 formed therein, and has through holes 18, through which a gas flows out, formed in the bottom thereof. Compared with the case where the balanced transmission line is entirely disposed on the atmospheric pressure side, a uniform electromagnetic field generated by the conductors can be utilized effectively.

In this case, a high-frequency wave is introduced through the side of the chamber. If the balanced transmission line is shaped spirally, a load that presents a load impedance is connected to the balanced transmission line at the center thereof. If the balanced transmission line is shaped tortuously, the load presenting a load impedance is connected to the opposite ends thereof. The load may be arranged through the dielectric plate.

In this case, the balanced transmission line 4 comprises the conductors 4a and 4b formed spirally on the front and back sides of the dielectric plate 15 having the gas passageway 17 formed therein. Alternatively, the conductors 4a and 4b may be formed spirally on the surfaces of two dielectric plates respectively. The dielectric plates may then be disposed with a desired space between them so that the back sides thereof will be opposed to each other. The space may be used as a gas passageway.

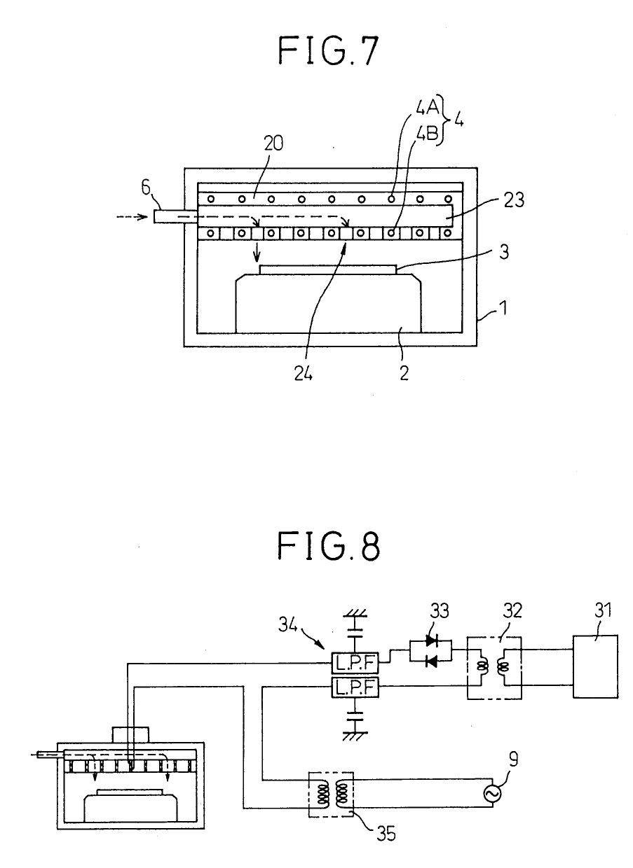

An embodiment shown in FIG. 7 (which shows a process chamber alone) has conductors 4a and 4b, which constitute a balanced transmission line 4, embedded in a dielectric plate 20. The pair of upper and lower conductors constitutes the balanced transmission line 4. A gas passageway 23 is formed between the conductors in the dielectric plate 20. A gas is allowed to flow out to a wafer through gas outlets 24 formed in the bottom of the dielectric plate. Similarly to the embodiment shown in FIG. 6, a uniform electromagnetic field generated between the conductors can be utilized effectively. Alternatively, two dielectric plates in which the conductors 4a and 4b are embedded respectively may be disposed with a space between them, and the space may be used as a gas passageway.

According to an embodiment of the present invention, a microstrip line may be used instead of a balanced transmission line. The uniformity of a generated electromagnetic field is similarly ensured.

The microstrip line has a strip conductor separated from a grounded conducting plane. Generally, a dielectric plate is interposed between the grounded conducting plane and strip conductor. When a microstrip line is substituted for a balanced transmission line, one side of a dielectric plate having a gas passageway therein is formed as a grounded conductive plane. A strip conductor is formed spirally or tortuously on the other side of the dielectric plate, and gas outlets are formed in the portion of the side other than the portion thereof having the strip conductor. Thus, a microstrip coil is made. The strip conductor of the microstrip coil is disposed on a vacuum side of a process chamber.

A gas is introduced through a gas inlet by way of the gas passageway formed in the dielectric plate. The gas is ionized by a uniform electromagnetic field generated around the microstrip line. Consequently, the gas plasma flows into the top of a wafer.

In order to introduce a high-frequency power, a coaxial cable is directly connected to the microstrip line. Moreover, the dielectric plate may not be employed, but a wire may be disposed while being separated from the grounded conducting plane. Thus, a strip line may be made. Even in this case, at least the wire is disposed on a reduced pressure side of a processing chamber, and a gas is introduced into the space between the grounded conducting plane and the wire.

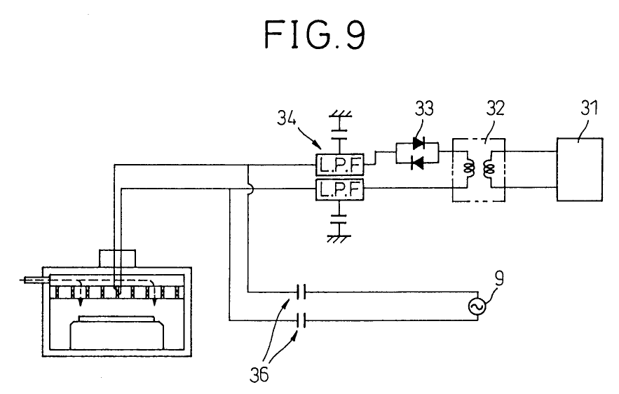

Apparatus shown in FIG. 8 or FIG. 9 utilizes a balanced transmission line located in a process chamber as a heater. It is noted that a heater is used for setting a plasma environment to an appropriate temperature. The apparatus uses a balanced transmission line as a heater, wherein a heater direct current is fed from an ac power supply 31 to the balanced transmission line via a transformer 32, a full-wave rectifier 33, and a smoothing circuit 34.

In the apparatus shown in FIG. 8, a high-frequency power supply 9 for use in generating an electromagnetic field feeds a high-frequency current, which is superposed on a heater direct current, via a transformer 35 whose secondary winding is connected in series with a heater power supply. Moreover, in the apparatus shown in FIG. 9, a high-frequency power supply 9 for use in inducing an electromagnetic field is connected in parallel with a heater power supply line via a coupling capacitor 36. The high-frequency power supply 9 feeds a high-frequency current while superposing it on a heater direct current.

Owing to the above circuitry, the apparatus having a simple configuration need not separately include a heater.

As described so far, according to the present invention, since a balanced transmission line is employed, a high-frequency power can be efficiently transmitted, and a uniform electromagnetic field can be generated and used to produce plasma. Moreover, since the characteristic impedance of the balanced transmission line does not depend on a frequency, the present invention can cope with a wide range of frequencies.

1. Plasma processing apparatus that produces gas plasma in a vacuum chamber by generating an electromagnetic field so as to treat an object in the vacuum chamber by the plasma, comprising:
a balanced transmission line that is connected to a high-frequency power supply to generate said electromagnetic field, the balanced transmission line comprising two parallel conductors which are horizontal and disposed one above the other, and
a gas inlet formed between said two parallel conductors to introduce gas into space between the two parallel conductors, so as to flow the gas to said object.

2. Plasma processing apparatus according to claim 1, wherein said two conductors are disposed respectively on the top and the bottom of a dielectric member, the space between the top and the bottom of said dielectric member is used as a gas passageway, and a gas outlet is formed in the bottom of said dielectric member so as to flow the gas to said object.

3. Plasma processing apparatus according to claim 2, wherein said two conductors are embedded respectively on the top and the bottom of a dielectric member, the space between the top and the bottom of said dielectric member is used as a gas passageway, and a gas outlet is formed in the bottom of said dielectric member so as to flow the gas to said object.

4. Plasma processing apparatus according to claim 2, wherein said one of said two conductors is embedded in an upper dielectric plate, the other of said two conductors is embedded in a lower dielectric plate, and the space between the upper and lower dielectric plates is used as a gas passageway, and a gas outlet is formed in the lower dielectric plate so as to flow the gas to said object.

5. Plasma processing apparatus according to claim 1, wherein said two parallel conductors are connected to a direct current source and working as a heater.

6. Plasma processing apparatus according to claim 5, wherein a high-frequency current fed from said high-frequency power supply and the direct current fed from said direct current source are superposed on said two parallel conductors.
